(19) United States
(12) Patent Application Publication
(10) Pub. No.: US 2007/0170947 A1
(43) Pub. Date: Jul. 26, 2007

(54) Method and an apparatus for measuring FET properties

(76) Inventor: Kazuhisa Utada, Tokyo (JP)

Correspondence Address: Paul D. Greeley;Ohlandt, Greeley, Ruggiero & Perle, L.L.P., 10th Floor, One Landmark Square, Stamford, CT, 06901-2682, US

(21) Appl. No.: 11/605,498

(22) Filed: Nov. 29, 2006

(30) Foreign Application Priority Data
Jan. 25, 2006 (JP) 2006-016275

(51) Int. Cl. G01R 31/26

(52) U.S. Cl. 324/769

(57) ABSTRACT

An apparatus for measuring the properties of FET by generating a pulse to be applied to gate G of FET and measuring the voltage dependent on the drain current flowing to FET in response to the pulse, comprising a pulse generator for generating a pulse; a directional element disposed behind pulse generator; and voltage measuring device for measuring voltage.

### FIELD OF THE INVENTION

The present disclosure relates to technology for measuring the current-voltage properties of an FET by applying pulse signals to the gate of an FET and measuring the drain current flowing in response to the pulse signals.

### DISCUSSION OF THE BACKGROUND ART

The current-voltage properties (IV properties hereinafter) of an FET are measured by applying a predetermined pulse voltage to the gate of an FET in a state wherein a predetermined bias voltage has been applied to the drain of the FET (for instance, refer to Jenkins, K. A., Sun, J. Y.-C., Measurement of I-V curves of silicon-on-insulator (SOI) MOSFETs without self-heating, Issue 4, Volume 16, Electron Device Letters, IEEE, April, 1995, p. 145-147). By means of this measuring method, the properties of an FET that uses SOI or strained silicon are measured without any effect due to the generation of heat by the FET itself. Moreover, the reduction in the drain current drive power can be controlled and thereby a high-precision measurement can be achieved when measuring the properties of a MOSFET that uses high-k gate insulation film (high k gate oxide). See also JP Unexamined Patent Application (Kokai) 2004-205301 (FIG. 15).

There are cases of measurement using pulses as described above wherein there is a reduction in measurement accuracy due to impedance mismatches of the transmission path through which the pulses travel. Therefore, an terminal element that is element for electrically termination is connected to a terminal or near a terminal of the FET to which pulses are input in order to improve measurement accuracy. As a result, the measurement accuracy of the wave amplitude of the pulses applied to the FET rises and the measurement accuracy of the FET properties improves. However, tools such as probe cards for measuring the FET on a wafer and multiplexers for switching the FET connected to the measuring apparatus are disposed between the measuring apparatus and the FET. In this case, the terminal element is near the terminal inside the tool to which the FET is connected or near the terminal inside the multiplexer on the FET side. There are times when this terminal element interferes with other types of measurements and tests. For instance, it is preferred that this type of end terminal not be present when measuring the S parameter because it is included in the network properties of the FET. Consequently, there is a need to provide technology for measuring the IV properties of the FET such that the properties of the FET can be measured with the same or better measurement accuracy than in the past.

### SUMMARY OF THE INVENTION

The first subject of the invention is a method for measuring the properties of an FET comprising a step for applying a pulse to an FET gate, a step for measuring the voltage of the pulse, and a step for measuring the voltage dependent on the drain current flowing to the FET in response to the pulse, characterized in that the step for applying a pulse is a step for applying the pulse to the gate by means of a directional element.

The second subject of the invention is the method of the first subject of the invention, further characterized in that the output impedance of the directional element is the same as the characteristic impedance of the circuit connected to the output terminal of the directional element.

The third subject of the invention is the method of the first or second subject of the invention, further characterized in that the input impedance of the directional element is the same as the directional impedance of the circuit connected to the input terminal of the directional element.

The fourth subject of the invention is the method of the first, second, or third subject of the invention, further characterized in that the step for applying a pulse is a step whereby the pulse is applied to the gate after going through the directional element and then a Bias-T.

The fifth subject of the invention is an apparatus for measuring the properties of an FET by generating a pulse to be applied to the gate of the FET and measuring the voltage dependent on the drain current flowing to the FET in response to this pulse, characterized in that it comprises a pulse generator for generating the pulse; a directional element disposed between the pulse generator and the gate of the FET; and voltage measuring means for measuring the voltage.

The sixth subject of the invention is the apparatus of the fifth subject of the invention, further characterized in that the output impedance of the directional element is the same as the characteristic impedance of the circuit connected to the output terminal of the directional element.

The seventh subject of the invention is the apparatus of the fifth or sixth subject of the invention, further characterized in that the input impedance of the directional element is the same as the characteristic impedance of the circuit connected to the input terminal of the directional element.

The eighth subject of the invention is the apparatus of the fifth, sixth, or seventh subject of the invention, further characterized in that it also comprises a Bias-T for adding bias to the pulse, and in that the Bias-T is disposed between the directional element and the gate of the FET.

The ninth subject of the invention is a system for measuring the properties of an FET by generating a pulse to be applied to the gate of the FET and measuring the voltage dependent on the drain current flowing to the FET in response to the pulse, characterized in that it comprises a pulse generator for generating the pulse; a directional element disposed between the pulse generator and the gate of the FET; a switch for selecting the predetermined FET from multiple FETs and electrically connecting the gate of the selected FET to the directional element; voltage measuring means for measuring the voltage; and a switch for selecting a predetermined FET from multiple FETs and electrically connecting the drain of the selected FET to the voltage measuring means.

The tenth subject of the invention is the measuring system of the ninth subject of the invention, further characterized in that the output impedance of the directional element is the same as the characteristic impedance of a circuit connected to the output terminal of the directional element.

The eleventh subject of the invention is the measuring system of the ninth or tenth subject of the invention, further characterized in that the input impedance of the directional element is the same as the characteristic impedance of the circuit connected to the input terminal of the directional element.

The twelfth subject of the invention is the measuring system of the ninth, tenth, or eleventh subject of the invention, further characterized in that it also comprises a Bias-T for adding bias to the pulse, and in that the directional element is in front of the Bias-T.

The directional element is an element that has directivity for signal transmission. In further detail, the directional element is an element having two or more ports or terminals whereby signals are transmitted in one direction between two predetermined ports or two predetermined terminals, while signal transmission in the opposite direction is prevented. The isolation properties in this opposite direction are only necessary for satisfying measurement accuracy. A specific example of a directional element is a buffer, isolation amp, directional coupler or circulator.

By means of the present disclosure, a pulse is applied to an FET through a directional element; therefore, an terminal element is not necessary in order to improve the measurement accuracy. Moreover, the output impedance of the directional element is equal to the characteristic impedance of the circuit connected to the output terminal of the directional element; therefore, it is possible to prevent multiple reflection of pulses between the directional element and the gate of the FET, which is the object under test. Furthermore, the input impedance of the directional element is equal to the characteristic impedance of the circuit connected to the input terminal of the directional element; therefore, it is possible to prevent multiple reflection of pulses inside the circuit in front of the directional element. Moreover, the directional element is disposed in front of a Bias-T; therefore, the directional element need not deal with the direct current component.

### BRIEF DESCRIPTION OF THE DRAWINGS

FIG. 1 is a drawing showing the structure of measuring system 1, which is an embodiment of the present disclosure.

FIG. 2 is a drawing showing the structure of measuring apparatus 200 inside measuring system 10.

FIG. 3 is a drawing showing the equivalent circuit when FET 500 is measured by measuring system 10.

FIG. 4 is a diagram showing changes in voltage at the main points inside measuring system 10.

### DETAILED DESCRIPTION OF THE PREFERRED EMBODIMENT

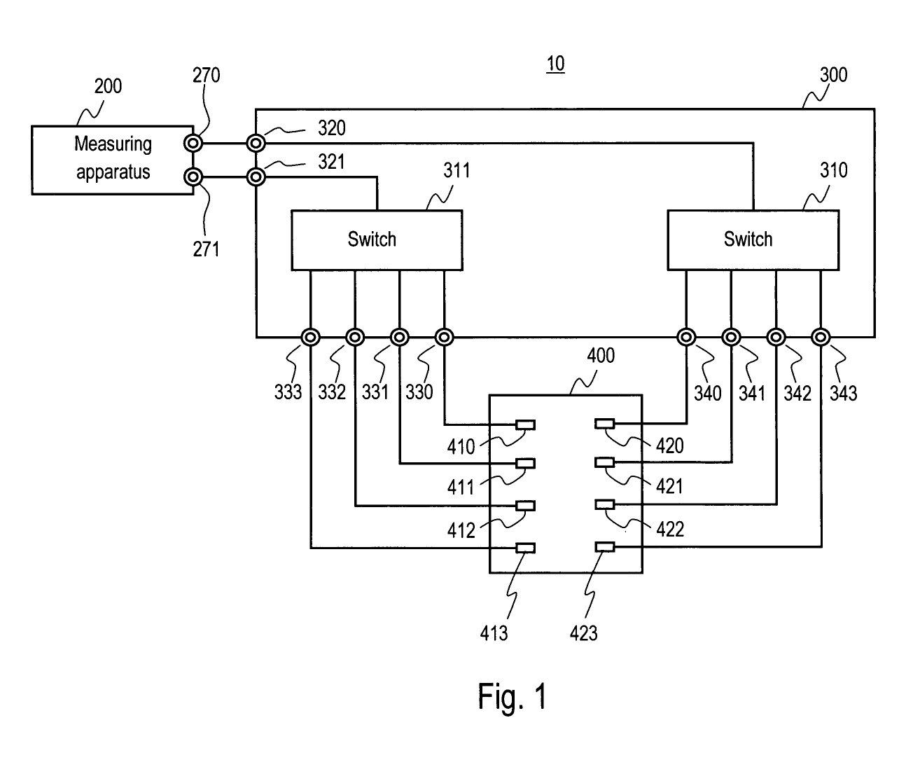

Embodiments of the present disclosure will now be described while referring to the attached drawings. First, an embodiment of the present disclosure is a measuring system 10 for measuring the properties of an FET. Refer to FIG. 1. FIG. 1 is a block diagram showing the general structure of measuring system 10. First, the structure of measuring system 10 will be described and then the method for measuring the properties of an FET using measuring system 10 will be described.

Measuring system 10 comprises a measuring apparatus 200, a multiplexer 300, and a probe card 400. Measuring apparatus 200 is an apparatus for generating a pulse and measuring current. Measuring apparatus 200 has a port 270 for outputting pulses and a port 271 for measuring current. The internal structure of measuring apparatus 200 will not be described in detail here. Multiplexer switch 300 comprises single-pole, four-throw (1P4T)-type switches 310 and 311. Switch 310 is the apparatus for selectively connecting port 320 electrically with one of ports 340 through 343. Switch 311 is the apparatus for selectively connecting port 321 electrically with one of ports 330 to 333. Port 320 is connected to port 270 of measuring apparatus 200. Port 321 is connected to port 271 of measuring apparatus 200. Probe card 400 is a tool for contacting the FET (not illustrated), or the object under measurement on the wafer. Probe card 400 has pads 410 through 413 and 420 through 423 for contacting the FET (not illustrated). Pads 410 and 420, pads 411 and 421, pads 412 and 422, and pads 413 and 423 form pairs. Pads 410 through 413 are electrically connected to the drain (not illustrated) of the FET. Pad 410 and port 330, pad 411 and port 331, pad 412 and port 332, pad 413 and port 333, pad 420 and port 340, pad 421 and port 341, pad 422 and port 342, and pad 423 and port 343 are connected to one another.

The output impedance at port 270 of measuring apparatus 200 and the input impedance at port 271 of measuring apparatus 200 are each 50Ω. Moreover, the characteristic impedance is 50Ω at the transmission path between measuring apparatus 200 and switch 300, the transmission path inside switch 300, the transmission path between switch 300 and probe card 400, and the transmission path inside probe card 400.

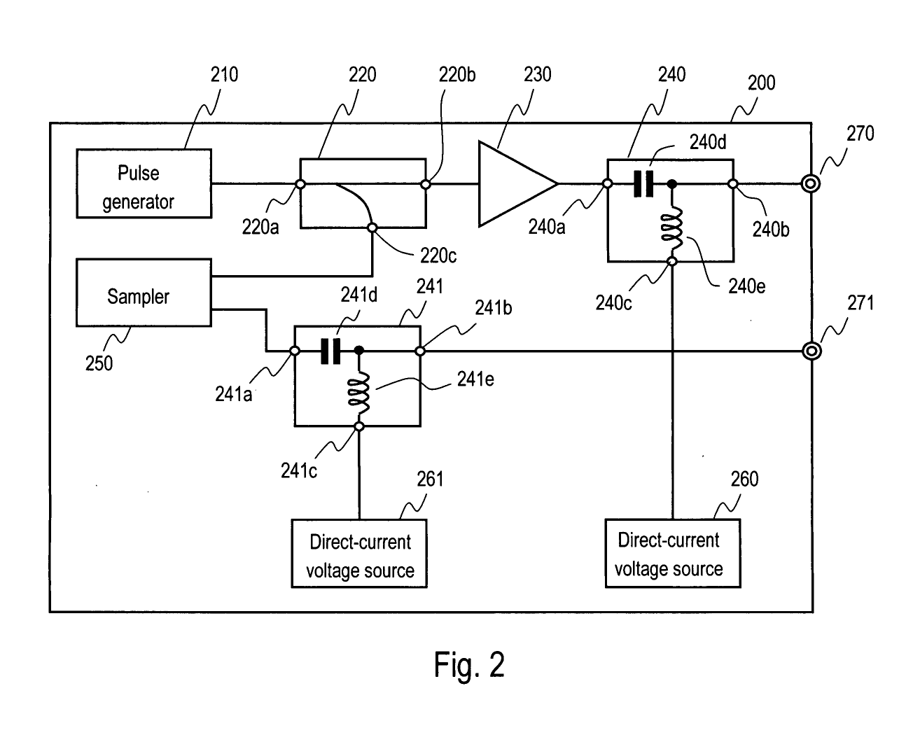

Next, the internal structure of measuring apparatus 200 will be described while referring to FIG. 2. Measuring apparatus 200 comprises a pulse generator 210, a splitter 220, a buffer amp 230, a Bias-T 240, a Bias-T 241, a sampler 250, a direct-current voltage source 260, a direct-current voltage source 261, a port 270, and a port 271.

Pulse generator 210 is an apparatus for generating a pulse having any width and any wave amplitude. Pulse generator 210 can be, for instance, the pulse generator Model 81110A made by Agilent Technologies. Splitter 220 is a distributor composed of a circuit wherein at least three resistors of 50/3Ω (=approximately 16.7Ω each) are connected in a Y-shape. Splitter 220 has a first terminal 220a, a second terminal 220b, and a third terminal 220c. Signals input to any one of terminals 220a through 220c are divided by a ratio of 1:1 and the divided signals are output to the other two terminals. First terminal 220a of splitter 220 is connected to pulse generator 210, second terminal 220b is connected to buffer amp 230, and third terminal 220c is connected to sampler 250. The distribution ratio of 220 should be known, and can be a ratio other than 1:1. Moreover, splitter 220 can also be a distribution circuit other than a Y-shaped resistance distribution circuit (for instance, a delta-shaped resistance distribution circuit). Buffer amp 230 is the apparatus for outputting signals having a voltage amplitude that is of the same amplification as the input signals. It should be noted that the amplification factor of buffer amp 230 is not necessarily the same amplification and can be another factor as long as it is known. The isolation of buffer amp 230, that is, the attenuation rate, is 40 dB or greater in the direction from the output terminal of buffer amp 230 toward the input terminal of buffer amp 230. It should be noted that the lower limit of the isolation of buffer amp 230 is determined by the desired measurement accuracy.

First terminal 240a of Bias-T 240 is connected to buffer amp 230, second terminal 240b is connected to port 270, and third terminal 240c is connected to direct-current voltage source 260. A capacitor 240d for preventing direct current is disposed between first terminal 240a and second terminal 240b. An inductor 240e for preventing alternating current is disposed between second terminal 240b and third terminal 240c. First terminal 241a of Bias-T 241 is connected to sampler 250, second terminal 241b is connected to port 271, and third terminal 241c is connected to direct-current voltage source 261. A capacitor 241d for preventing direct-current is disposed between first terminal 241a and second terminal 241b. Moreover, an inductor 241e for preventing alternating current is disposed in between second terminal 241b and third terminal 241c. Direct-current voltage sources 260 and 261 are apparatuses for outputting direct current of the desired voltage level. Direct current voltage sources 260 and 261 can be, for instance, an SMU (source major unit) such as the E5262A made by Agilent Technologies. Sampler 250 is an apparatus for sampling the input signals and measuring the wave amplitude of the pulse as voltage. An example of sampler 250 is an oscilloscope such as the 54854A made by Agilent Technologies.

It should be noted that the output impedance of pulse generator 210, the input impedance and the output impedance of buffer amp 230, the input impedance of sampler 250, and the characteristic impedance of the transmission paths between each structural element of measuring apparatus 200 are each 50Ω. Moreover, the characteristic impedance for pulse is regarded as 50Ω between terminals 240a and 240b of Bias-T 240 and between terminals 241a and 241b of Bias-T 241.

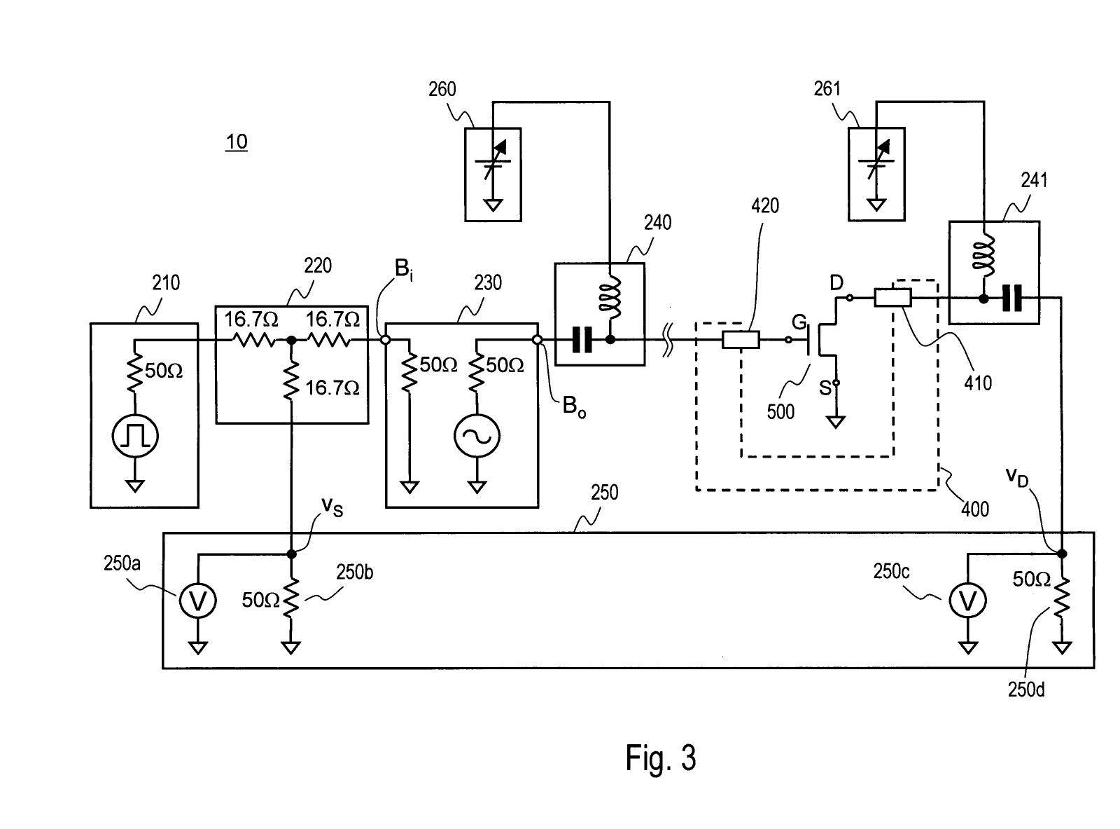

Next, refer to FIG. 3. FIG. 3 is a drawing of a simplified representation of the equivalent circuit of the measuring system when an FET 500, which is electrically connected between pads 410 and 420 is measured. Although not shown in FIG. 3, switch 310 selects port 340 and switch 311 selects port 330 in order to measure FET 500. A detailed description of each of the elements in FIG. 3 that is the same as in FIGS. 1 and 2 is omitted.

The method for measuring the I-V properties of FET 500 using measuring system 10 will now be described while referring to FIG. 3. First, a voltage pulse having a predetermined wave amplitude is generated by pulse generator 210. The generated pulse is distributed 1:1 by splitter 220 and input to buffer amp 230 and sampler 250. Once the pulse that has been input to buffer amp 230 is amplified at buffer 230, bias is applied at Bias-T 240, and the pulse reaches gate G of FET 500. Direct-current voltage is applied through Bias-T 241 to drain D of FET 500 by direct-current voltage source 261. Pulsed drain current flows to FET 500 in response to the biased pulse. The change in the pulse shape of the drain current is converted to a change in voltage by an input impedance 250d and measured by a voltammeter 250c. Sampler 250 measures the pulse input from splitter 240 by a voltammeter 250a simultaneously with measurement of the drain current. The I-V properties of FET 500 are obtained by conducting the above-mentioned drain current measurement and gate pulse voltage measurement based on various drain bias voltage values and various gate pulse voltage values.

However, while the characteristic impedance of the transmission path from the output terminal of buffer amp 230 to gate G of FET 500 is 50Ω, the impedance at gate G of FET 500 is 1 kΩ to several kΩ. Moreover, as is clear from FIG. 3, there is no terminal element in the vicinity of gate G of FET 500 and anywhere in the transmission path from the output terminal of buffer amp 230 up to gate G of FET 500. Consequently, the voltage pulse output from measuring apparatus 200 (port 270) passes through multiplexer 300 (FIG. 1) and probe card 400, reaches gate G of FET 500, and is reflected by gate G. The reflected voltage pulse moves back thorough probe card 400 and multiplexer 300 (FIG. 1) and reaches measuring apparatus 200. The reflected voltage pulse further reaches buffer amp 230 and is absorbed by the output impedance of buffer amp 230.

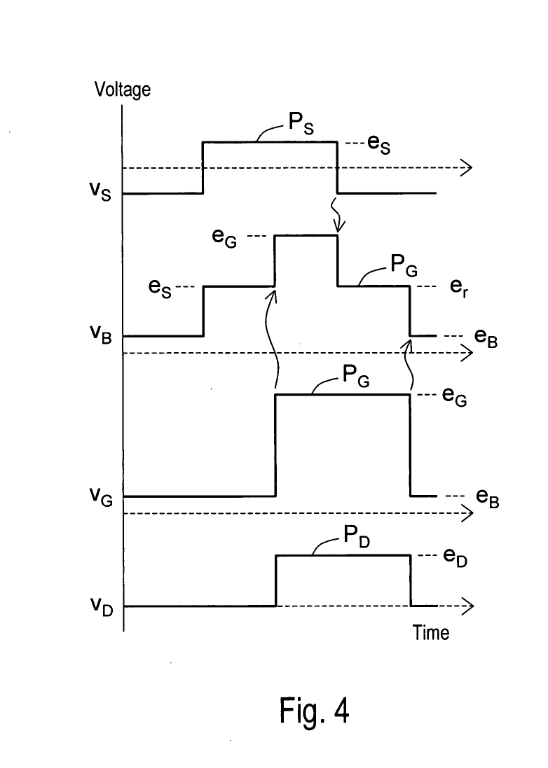

Refer to FIGS. 3 and 4. FIG. 4 is a diagram showing changes over time in the measured voltage V_{S} of voltammeter 250a, the voltage V_{G} of gate G, and the measured voltage V_{D} of voltammeter 250c. When pulse generator 210 generates a pulse, a pulse Pₛ having wave height eₛ is measured by voltammeter 250a for a time. Moreover, after a certain time, a pulse P_{G} having a pulse height e_{G} appears at gate G. Drain current flows to FET 500 in response to a pulse P_{G}, and a pulse P_{D} having a wave height e_{D} is measured by voltammeter 250c. Wave height e_{D} is the drain current flowing to FET 500 that has been converted to voltage by input impedance 250d and is dependent on the drain current. A voltage V_{B} is the voltage at output terminal Bo of buffer amp 230. Voltage V_{B} is initially at wave height e_{S} that is the same as the pulse at input terminal Bᵢ of buffer 230. Wave height e_{S} is the wave amplitude of the pulse wave that moves forward from output terminal Bo to gate G. Then reflected pulse waves from gate G reach output terminal Bo. Reflected pulse waves (with a wave height of eᵣ) are added to the forward moving pulse waves (wave height eₛ) at this time; therefore, voltage V_{B} changes to wave height e_{G}. As time passes, only reflected pulse waves are present at output terminal Bo and voltage V_{B} changes to eᵣ. As is clear from FIG. 4, voltammeter 250a is not affected by the reflected pulse from gate G. e_{B} and e_{G} are represented by the following formula when the impedance of FET 500 at gate G is Z_{L}.

$${e}_{G} = \frac{2 {Z}_{L}}{{Z}_{L} + 50} {e}_{s} \\ {e}_{r} = \frac{{Z}_{L} - 50}{{Z}_{L} + 50} {e}_{s} \qquad [ Mathematical formula 1 ]$$

Thus, because buffer amp 230 having the same output impedance as the characteristic impedance of the transmission path from the output terminal of buffer amp 230 to gate G of FET 500 is disposed behind splitter 220, a multiple reflection of pulses does not occur between buffer amp 230 and gate G, and reflected pulses are kept from reaching sampler 250. Furthermore, the output impedance of pulse generator 210, the characteristic impedance of splitter 220, the input impedance of buffer amp 230, and the input impedance of sampler 250 are the same; therefore, there is no reflection of pulses between pulse generator 210, buffer amp 230, and sampler 250. Buffer amp 230 further is disposed in front of Bias-T 240 and a pulse composed only of alternating-current component should be amplified by buffer amp 230. Consequently, the band width required by buffer amp 230 can be narrower than when a pulse containing a direct-current component is amplified.

Buffer amp 230 of the above-mentioned embodiments can be replaced by a directional coupler, circulator, or other directional element.

When the input impedance of the oscilloscope used as sampler 250 in the above-mentioned embodiment is greater than 50Ω, for instance, 1 to several MΩ, a resistor is connected in parallel with the input terminal of sampler 250 in order to make the input impedance of sampler 250 equivalent at 50Ω.

What is claimed is:

1. A method for measuring the properties of an FET comprising:
applying a pulse to an FET gate by means of a directional element;
measuring the voltage of the pulse; and
measuring the voltage dependent on the drain current flowing to the FET in response to the pulse.

2. The measuring method according to claim 1, wherein an output impedance of said directional element is the same as a characteristic impedance of a circuit connected to an output terminal of said directional element.

3. The measuring method according to claim 1, wherein an input impedance of said directional element is the same as a directional impedance of a circuit connected to an input terminal of said directional element.

4. The measuring method according to claim 1, wherein said pulse is applied to FET gate after going through said directional element and then a Bias-T.

5. A measuring apparatus for measuring the properties of an FET by generating a pulse to be applied to a gate of said FET; and measuring a voltage dependent on a drain current flowing to said FET in response to said pulse, said measuring apparatus comprising:
a pulse generator for generating said pulse;
a directional element disposed between said pulse generator and said gate of said FET; and
voltage measuring unit that measures said voltage.

6. The measuring apparatus according to claim 5, wherein an output impedance of said directional element is the same as a characteristic impedance of a circuit connected to an output terminal of said directional element.

7. The measuring apparatus according to claim 5, wherein an input impedance of said directional element is the same as a characteristic impedance of a circuit connected to an input terminal of said directional element.

8. The measuring apparatus according to claim 5, further comprising a Bias-T for adding bias to said pulse, and wherein said Bias-T is disposed between said directional element and said gate of said FET.

9. A system for measuring the properties of a predetermined FET by generating a pulse to be applied to a gate of said FET and measuring a voltage dependent on a drain current flowing to said FET in response to said pulse, said measuring system comprising:
a pulse generator for generating the pulse;
a directional element disposed behind said pulse generator;
a switch for selecting said predetermined FET from a plurality of FETs and electrically connecting said gate of said predetermined FET to a directional element;
voltage measuring device that measures said voltage; and
a switch for selecting said predetermined FET from a plurality of FETs and electrically connecting a drain of said predetermined FET to said voltage measuring device.

10. The measuring system according to claim 9, wherein an output impedance of said directional element is the same as a characteristic impedance of a circuit connected to said output terminal of said directional element.

11. The measuring system according to claim 9, wherein said input impedance of said directional element is the same as a characteristic impedance of a circuit connected to an input terminal of said directional element.

12. The measuring system according to claim 9, further comprising a Bias-T that adds bias to said pulse, and wherein said Bias-T is disposed between said directional element and said gate of said FET.
